(19) United States
(12) Patent Application Publication
(10) Pub. No.: US 2006/0284223 A1
(43) Pub. Date: Dec. 21, 2006

(54) CMOS image sensor and manufacturing method thereof

(75) Inventor: Jin Han Kim, Icheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/471,244

(22) Filed: Jun. 19, 2006

(30) Foreign Application Priority Data
Jun. 17, 2005 (KR) 10-2005-0052377

(51) Int. Cl. H01L 31/113; H01L 21/336

(52) U.S. Cl. 257/292; 257/382; 438/300; 257/E27.133

(57) ABSTRACT

Disclosed are a CMOS image sensor and manufacturing method thereof. The method includes the steps of forming a lower insulating layer and an upper insulating layer on an entire surface of a semiconductor substrate in successive order, the substrate having an isolation layer defining an active region comprising a photodiode region and a transistor region, the transistor region having a gate thereon, the gate comprising a gate insulating layer and a gate electrode, and having insulating sidewalls on sides thereof; removing the upper and lower insulating layers from region(s) other than the photodiode region; forming a metal layer on the surface of the semiconductor substrate; and annealing the substrate to selectively form a salicide layer on a surface of the semiconductor substrate (other than the photodiode region).

This application claims the benefit of Korean Patent Application No. 10-2005-0052377, filed on Jun. 17, 2005, which is incorporated by reference herein in its entirety.

### BACKGROUND OF THE INVENTION

1. Field of the Invention

The present invention relates to an image sensor, more specifically, to a complementary metal oxide semiconductor (CMOS) image sensor and manufacturing method thereof.

2. Description of the Related Art

Conventionally, an image sensor, as a kind of semiconductor device, transforms optical images into electrical signals. Image sensors can be generally classified into charge coupled devices (CCDs) and CMOS image sensors.

A CCD comprises a plurality of photo diodes arranged in the form of matrix to transform optical signals into electrical signals, a plurality of vertical charge coupled devices (VCCDs) formed between the photo diodes to transmit charges generated in each photo diode in a vertical direction, a plurality of horizontal charge coupled devices (HCCDs) for transmitting charges from each VCCD in a horizontal direction, and a sense amplifier for sensing charges transmitted in the horizontal direction to output electrical signals.

It has been generally known that CCDs have complicated operational mechanisms, and high power consumption. In addition, its manufacturing method is relatively complicated, because multiple photolithography steps are required in its fabrication. Especially, it is difficult to integrate a CCD with other devices such as control circuits, signal processing circuits, analog/digital converters, etc., in a single chip. Such disadvantages of a CCD may hinder miniaturization of products containing a CCD.

In order to overcome above described disadvantages of CCDs, CMOS image sensors have been recently developed as the oncoming generation of image sensor. A CMOS image sensor generally comprises MOS transistors formed in a semiconductor substrate by CMOS fabrication technologies. In a CMOS image sensor, the MOS transistors are formed relative to the number of unit pixels, along with peripheral circuits such as control circuits, signal processing circuits, and the like. CMOS image sensors employ a switching mode that MOS transistors successively detect the output of each pixel.

More specifically, CMOS image sensors comprise a photo diode and MOS transistors in each pixel, thereby successively detecting electrical signals of each pixel in a switching mode to express a given image.

The CMOS image sensor has advantages such as low power consumption and relatively simple fabrication process. In addition, CMOS image sensors can be integrated with control circuits, signal processing circuits, analog/digital converters, etc., because such circuits can be manufactured using CMOS manufacturing technologies, which enables miniaturization of products.

CMOS image sensors have been widely used in a variety of applications such as digital still cameras, digital video cameras, and the like.

Meanwhile, CMOS image sensors can also be classified into 3T, 4T, 5T types, etc., according to the number of transistors in a unit pixel. The 3T type of CMOS image sensor comprises one photo diode and three transistors, and the 4T type comprises one photo diode and four transistors. Here, a circuit diagram and a unit pixel layout of the 3T type CMOS image sensor are configured as follows.

FIG. 1 is a circuit diagram of a conventional CMOS image sensor, and FIG. 2 is a layout illustrating a unit pixel in the conventional 3T type CMOS image sensor.

As shown in FIG. 1, a unit pixel of the conventional 3T type CMOS image sensor comprises one photo diode PD and three NMOS transistors T1, T2, and T3. A cathode of the photo diode PD is connected to a drain of the first NMOS transistor T1 and a gate of the second NMOS transistor T2.

Especially, sources of the first and second NMOS transistors T1 and T2 are connected to a supply terminal (VR) for supplying a standard voltage, and a gate of the first NMOS transistor T1 is connected to a reset terminal for supplying a reset signal.

In addition, a source of the third NMOS transistor T3 is connected to a drain of the second NMOS transistor T2, and a drain of the third NMOS transistor T3 is connected to a detecting circuit (not shown) via a signal line. Furthermore, a gate of the third NMOS transistor T3 is connected to a select signal line SLCT.

In general, the first NMOS transistor T1 is called a reset transistor Rx, the second NMOS transistor T2 is called a drive transistor Dx, and the third NMOS transistor T3 is called a select transistor Sx.

In the conventional 3T type CMOS image sensor, as shown in FIG. 2, one photo diode 20 is formed in a large portion of a defined active region 10, and three gate electrodes 30, 40, and 50 of the first to third transistors are respectively formed to be overlapped in other portion of the active region 10.

The first gate electrode 30 constitutes the reset transistor Rx. The second gate electrode 40 constitutes the drive transistor Dx. The third gate electrode 50 constitutes the select transistor Sx.

Here, dopant ions are implanted in the active region 10 where each transistor is formed, except for the portion of active region below each gate electrodes 30, 40, and 50, to form source and drain regions of each transistor.

Here, a supply voltage Vdd is applied to source/drain regions between the reset transistor Rx and the drive transistor Dx, and the source/drain regions formed at one side of the select transistor Sx is connected to detecting circuits (not shown).

In the above-described structure of CMOS image sensor, a reverse bias is applied to the photo diode PD, thus resulting in a depletion layer where electrons are generated by a light. When the reset transistor Rx turns off, the generated electrons lower the potential of the drive transistor Dx. Lowering of potential of the drive transistor proceeds continuously from turn-off of the reset transistor Rx, thus resulting in potential difference. The image sensor can be operated by detecting the potential difference as a signal.

FIGS. 3a to 3g are cross-sectional views successively illustrating a conventional method for manufacturing a CMOS image sensor, in view of A-A′ line in FIG. 2.

As shown in FIG. 3a, a low concentration of P-type epitaxial layer 62 is formed on a heavy concentration of a P++ type semiconductor substrate 61, using an epitaxial process. Here, the epitaxial layer 62 functions to form a deep and wide depletion region in the photo diode region. Thereby, the ability of a low-voltage photo diode for gathering photoelectrons can be improved, and also the light sensitivity can be improved.

Subsequently, after photolithographically masking an active region and exposing an isolation region on the semiconductor substrate 61, an isolation layer 63 is formed in the isolation region using a shallow trench isolation (STI) process or a local oxidation of silicon (LOCOS) process.

Next, a gate insulating layer 64 and a conductive layer (e.g., a heavy doped polysilicon layer) are deposited on the entire surface of the epitaxial layer 62, in successive order. The conductive layer and the gate insulating layer 64 are selectively patterned using photolithography and etching processes, thus forming the gate electrode 65. The gate insulating layer 64 can be formed using thermal oxidation process or chemical vapor deposition (CVD) process.

Referring to FIG. 3b, a first photoresist layer 66 is applied over the entire surface of the semiconductor substrate 61 including the gate electrode 65, and then it is patterned using exposure and development processes, thus covering the photo diode region and exposing the transistor region where source/drain regions will be formed.

Using the first photoresist pattern 66 as a mask, a low concentration of N-type dopant ions are implanted in the exposed transistor region to form a low concentration of N-type diffusion region 67.

As shown in FIG. 3c, after removal of the first photoresist pattern 66, a second photoresist layer 68 is applied over the semiconductor substrate 61, and then it is patterned using exposure and development processes, thus exposing the photo diode region.

Then, using the second photoresist pattern 68 as a mask, a low concentration of N-type dopant ions are implanted in the photo diode region, thus forming a low concentration of N-type diffusion region 69. Here, the low concentration of N-type diffusion region 69 is preferably formed at a depth greater than that of the low concentration of N-type diffusion region 67, using a higher implantation energy than that used to form N-type diffusion region 67.

As shown in FIG. 3d, after removing the second photoresist pattern 68, an insulating layer is formed over the entire surface of the substrate 61. Then, an etch back process is preformed on the insulating layer to form insulating sidewalls 70 on both sides of the gate electrode 65.

A third photoresist layer 71 is then formed over the entire surface of the substrate 61, and then it is patterned by exposure and development processes to cover the photo diode region and expose the transistor source/drain regions.

Using the third photoresist pattern 71 as a mask, a high concentration of N-type dopant ions are implanted in source/drain regions to form a high concentration of N-type diffusion region 72, i.e., a N+ type diffusion region.

As shown in FIG. 3e, a TEOS (Tetra Ethyl Ortho Silicate) oxide layer 80 for non-salicide (NSAL) treatment is deposited to a thickness of 1000 Å on the entire surface of the semiconductor substrate 61.

Then, a fourth photoresist layer 82 is applied over the entire surface of the substrate 61, and then it is patterned by exposure and development processes to cover the photo diode region and expose source/drain regions of each transistor.

Using a wet etch or dry etch process, a portion of the TEOS layer 80 that is exposed by the fourth photoresist pattern 82 is removed, then the substrate is cleaned or rinsed.

As shown in FIG. 3f, after cleaning the substrate 61, a metal layer 84 including a metal material, such as nickel, etc., is deposited on the entire surface of the substrate 61, using a physical vapor deposition (PVD) or chemical vapor deposition (CVD) process.

Then, as shown in FIG. 3g, the semiconductor substrate 61 undergoes a salicide process, thus selectively forming a salicide layer 73 on the gate electrode 65 and the portion of the substrate where the N+ type diffusion region 72 is formed.

In the above-described conventional CMOS image sensor, a salicide layer is not formed on the photo diode region, because the salicide layer generally reflects light. The photo diode region is configured to absorb light and transform it to electric charge. Accordingly, the NSAL treatment in the photo diode region is necessary to prevent formation of a salicide layer thereon, thus reducing dark current. For the same reason, a single pixel contact in the photo diode region is preferably a non-salicide contact.

However, the above-described conventional method for manufacturing a CMOS image sensor has problems as follows.

Namely, as shown in FIG. 3e, in the case where the TEOS oxide layer 80 is partially removed by a wet etch process, undercuts may occur inside the photo diode region despite the possibility of pixel design margin. Undercuts can induce salicidation of the photo diode region, thus resulting in invasion of the photo diode junction. Consequently, undercuts function as a source of current leakage, resulting in degrading the dark image characteristics and the yield of CMOS image sensors.

On the other hand, in the case where the TEOS oxide layer 80 is partially removed by a dry etch process in FIG. 3e, the oxide layer should remain in a thickness less than about 40 Å for the secure salicide formation. In this case, the silicon substrate can be damaged by plasma during the dry etch process, thus resulting in alteration of threshold voltages of transistors, especially PMOS transistors. More specifically, if the lattice structure in the vicinity of the silicon surface is damaged by plasma, boron ions having a high thermal diffusion ratio can diffuse into the damaged junction and channel regions during the subsequent thermal processes, resulting in a decrease in the threshold voltage of PMOS transistors. Accordingly, the range of fluctuation of threshold voltages becomes excessive, which leads to problems with reliability of the devices and/or uniformity or predictability of device behavior across an entire wafer.

### SUMMARY OF THE INVENTION

It is, therefore, an object of the present invention to provide a CMOS image sensor and manufacturing method thereof, which can reduce or prevent degradation of dark image characteristics of the image sensor, and improve threshold voltage uniformity of transistors constituting the image sensor. Ultimately, the present invention can increase the yield of CMOS image sensors.

To achieve the above object, an embodiment of a method for manufacturing a CMOS image sensor according to the present invention comprises the steps of: forming a lower insulating layer and an upper insulating layer on an entire surface of the semiconductor substrate in successive order, the substrate having an active region comprising a photodiode region and a transistor region, the transistor region having a gate thereon, the gate comprising a gate insulating layer, a gate electrode thereon and insulating sidewalls on sides of the gate electrode; removing the upper and lower insulating layers in a region other than the photo diode region; forming a metal layer on the surface of the semiconductor substrate; and annealing the semiconductor substrate to form a salicide layer on an exposed surface of the semiconductor substrate.

In addition, a CMOS image sensor manufactured by a method according to the present invention comprises: a semiconductor substrate including an isolation layer defining an active region, the active region comprising a photo diode region and a transistor region; a gate including a gate insulating layer and a gate electrode on the semiconductor substrate, generally in the transistor region; insulating sidewalls on sides of the gate electrode; lower and upper insulating layers on the photo diode region, the lower and upper insulating layers blocking a salicide layer from forming on the photo diode region; and a salicide layer on the transistor region.

These and other aspects of the invention will become evident by reference to the following description of the invention, often referring to the accompanying drawings.

### BRIEF DESCRIPTION OF DRAWINGS

FIG. 1 is a circuit diagram of unit pixel in a conventional CMOS image sensor.

FIG. 2 is a layout of unit pixel in a conventional CMOS image sensor.

FIGS. 3a to 3g are cross-sectional views successively illustrating a conventional method for manufacturing a CMOS image sensor, in a view of A-A′ line in FIG. 2.

FIGS. 4a to 4g are cross-sectional views successively illustrating a method for manufacturing a CMOS image sensor according to the present invention, in a view of A-A′ line in FIG. 2.

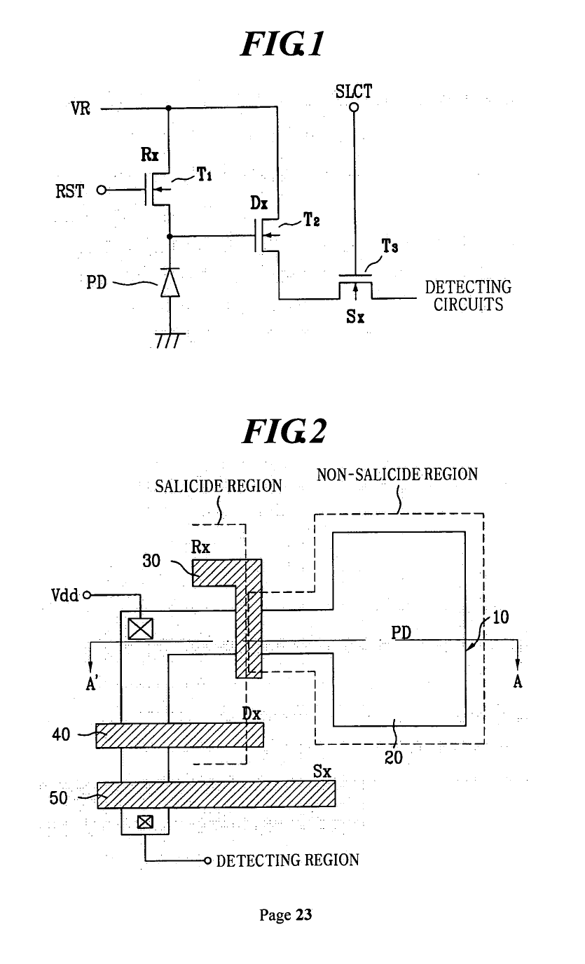

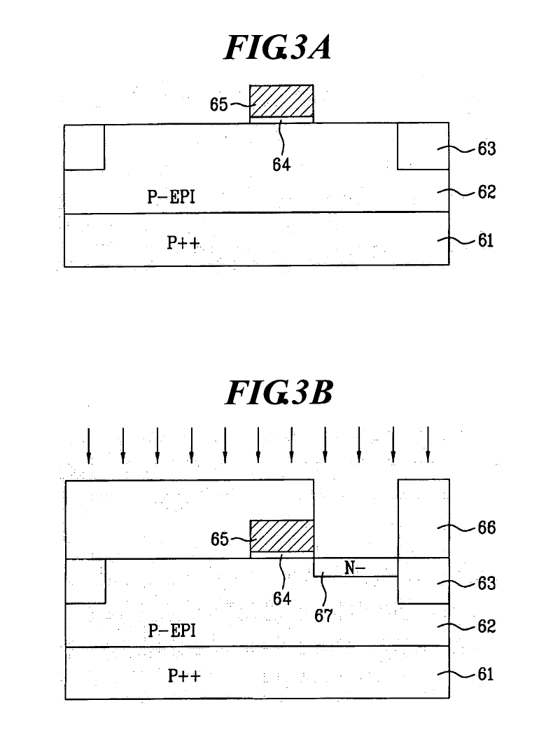

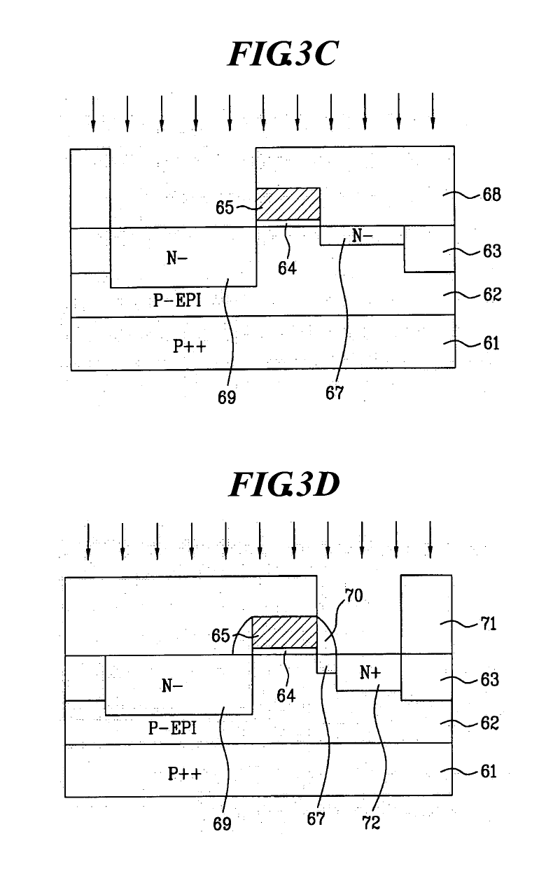

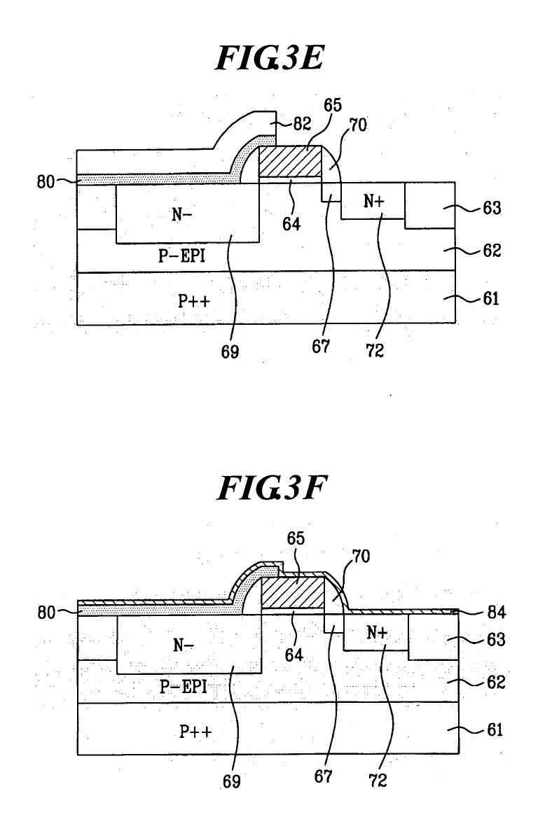

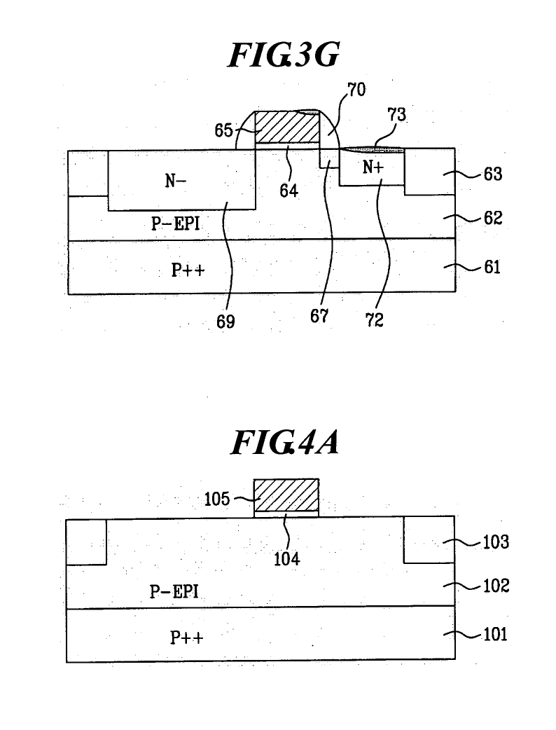

### DETAILED DESCRIPTION OF THE INVENTION

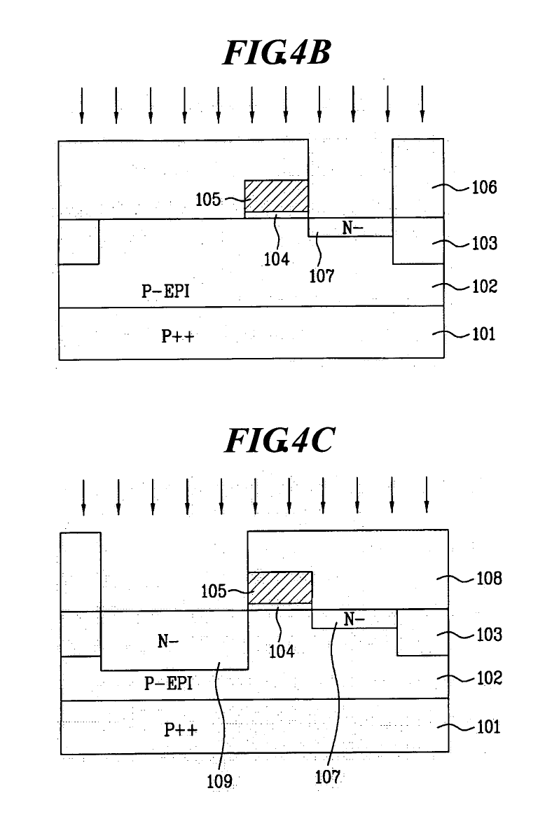

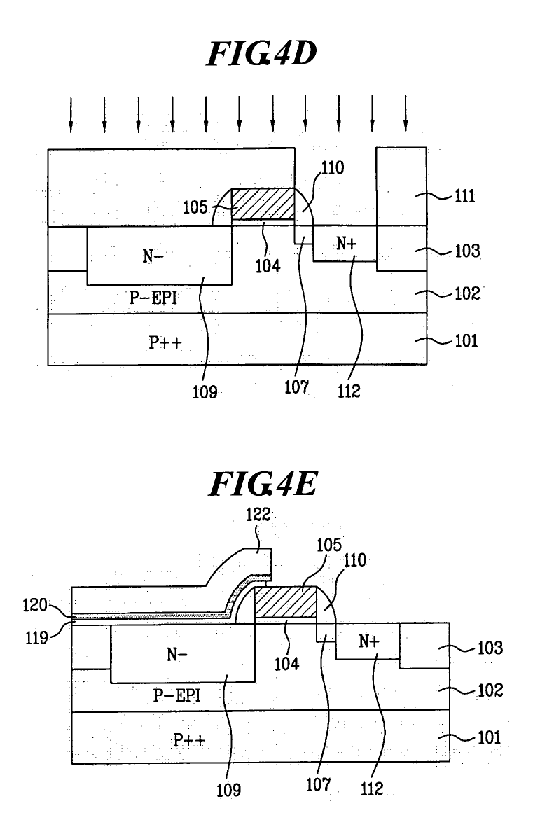

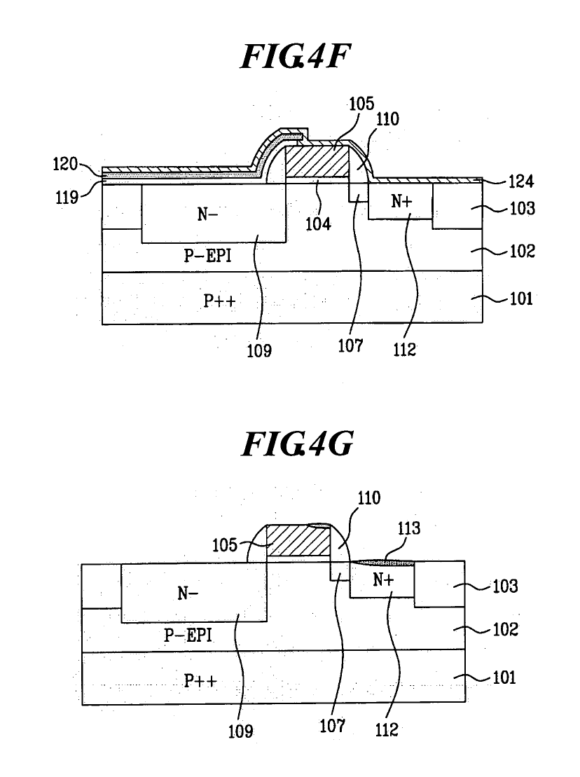

Hereinafter, an embodiment of a method for manufacturing a CMOS image sensor according to the present invention will be explained in successive order, referring to FIGS. 4a to 4g.

As shown in FIG. 4a, a P-type epitaxial layer 102 having a low concentration of dopant is formed on a P++ type semiconductor substrate 101 having a relatively heavy concentration of dopant, using an epitaxial process. Here, the epitaxial layer 102 functions to form a deep and wide depletion region in the photo diode region. Thereby, the ability of a low-voltage photo diode for gathering photoelectrons can be improved, and also the light sensitivity can be improved. Of course, the invention is not limited to this dopant type or these dopant concentrations, and a complementary dopant type, or doped layers that have a different concentration level, may be employed.

Subsequently, after photolithographically masking an active region and exposing an isolation region on the semiconductor substrate 101, an isolation layer 103 is formed in the isolation region using an STI or LOCOS process, thereby defining the active and isolation regions.

Next, a gate insulating layer 104 and a conductive layer (e.g., a heavily doped polysilicon layer) are deposited on the entire surface of the epitaxial layer 102, in successive order. The conductive layer and gate insulating layer are selectively patterned, thus forming the gate electrode 105. The gate insulating layer 104 can be formed using a thermal oxidation process or a CVD process.

Referring to FIG. 4b, a first photoresist layer 106 is applied over the entire surface of the substrate 101 including the gate electrode 105, and then it is patterned using exposure and development processes (e.g., photolithography), thus covering the photo diode region and exposing the transistor region where source/drain regions will be formed.

Using the first photoresist pattern 106 as a mask, a low concentration of N-type dopant ions are implanted in the exposed transistor region to form N-type diffusion region 107 (e.g., a lightly doped extension, or LDD, region). Depending on the type of dopant in the epitaxial layer 102, diffusion region 107 will generally have an opposite or complementary type.

As shown in FIG. 4c, after removal of the first photoresist pattern 106, a second photoresist layer 108 is applied over (or deposited on) the semiconductor substrate 101, and then it is patterned using exposure and development processes (e.g., photolithography), thus exposing the photo diode region.

Then, using the second photoresist pattern 108 as a mask, a low concentration of N-type dopant ions are implanted in the photo diode region, thus forming N-type diffusion region 109. Thus, the photodiode may comprise a low concentration implant region, which may be N-type. Here, the low concentration N-type diffusion region 109 is preferably formed to a depth greater than that of N-type diffusion region 107, preferably using a higher implantation energy.

As shown in FIG. 4d, after removing the second photoresist pattern 108, an insulating layer is formed over the entire surface of the substrate 101. Then, the insulating layer (which may comprise one or more layers of the same or different materials, such as silicon dioxide, silicon nitride, or a silicon nitride-on-silicon dioxide bilayer) is anisotropically etched (e.g., by an etch back process) to form insulating sidewalls 110 on sides of the gate electrode 105.

Next, a third photoresist layer 111 is formed over the entire surface of the substrate 101, and then it is patterned by exposure and development processes (e.g., photolithography) to cover the photo diode region and expose the transistor source/drain regions.

Using the third photoresist pattern 111 as a mask, a high concentration of N-type dopant ions are implanted in one or more source/drain regions (e.g., in the unit pixel) to form N-type diffusion region 112 (e.g., a N+ type diffusion region). Naturally, diffusion region 112 can be any type or concentration suitable for a source or drain terminal of a CMOS transistor, but it will generally have the same type as diffusion region 107, and at a higher concentration.

As shown in FIG. 4e, a lower insulating layer 119 and an upper insulating layer 120 are deposited in successive order, generally on the entire surface of semiconductor substrate 101 (e.g., by blanket deposition), for example using a low pressure CVD process (LPCVD). The lower and upper insulating layers 119 and 120 are used as salicide blocking layers, and they have a different etch selectivity from each other. For example, the upper insulating layer 120 may be etched with an etchant generally known to etch upper insulating layer 120 preferentially to lower insulating layer 119, under conditions such that the etch rate ratio of the upper insulating layer 120 to the lower insulating layer 119 is at least 5:1, 10:1, 20:1 or higher. Similarly, the lower insulating layer 119 may be etched with an etchant generally known to etch lower insulating layer 119 preferentially to upper insulating layer 120, under conditions such that the etch rate ratio of the lower insulating layer 119 to the upper insulating layer 120 is at least 10:1, 50:1, 100:1 or higher. The lower insulating layer 119 preferably has a thickness of from about 150 Å to about 200 Å and preferably comprises a material such as silicon nitride (SiN). In addition, the upper insulating layer 120 preferably has a thickness of from 300 Å to about 500 Å and preferably comprises an oxide (e.g., a silicon dioxide such as a TEOS-based oxide). Especially, the reason for using a LPCVD process is to prevent damage to the silicon substrate by plasmas. When plasma damage occurs, the leakage characteristics of the image sensor in dark and white states deteriorates, thus resulting in a decrease in the yield and/or performance of the devices.

Then, a fourth photoresist layer 122 is applied over the entire surface of the substrate 101, and then it is patterned by exposure and development processes (e.g., photolithography) to cover the photo diode region (and, optionally, part of the transistor gate electrode 105) and expose source/drain regions (e.g., 112) of each transistor.

Subsequently, the upper insulating layer 120 on the region which is exposed by the fourth photoresist pattern 122 is removed by a dry etching process using up to a 50% over etch ratio (and in one example, a 50% over etch ratio). Then, the semiconductor substrate 101 undergoes a cleaning process. In one such dry etch process, the upper insulating layer to be dry-etched is relatively thin, in comparison with a conventional example. In addition, because the lower insulating layer 119 having good etch-selectivity is below the upper insulating layer 120, plasma damage to the silicon substrate can be minimized during the dry etching process. Especially, in the conventional method, the insulating layer needs to remain in a thickness less than about 40 Å. However, in the present invention, it is unnecessary to keep the upper insulating layer, because the lower insulating layer 119 having a thickness greater than about 100 Å exists below the upper insulating layer 120.

Then, the lower insulating layer 119 in the region that is exposed by the fourth photoresist pattern 122 is removed by a wet etching process. Then, the semiconductor substrate 101 is cleaned or rinsed. Phosphoric acid (H₃PO₄) can be used as an etchant in the wet etching process to completely remove the lower insulating layer 119 in the region except for the photo diode region. In one such wet etching process, undercuts due to isotropic etching rarely occur inside the fourth photoresist pattern 122, because the deposition thickness (i.e., 150 Å˜200 Å) of the lower insulating layer 119 is relatively thin.

As shown in FIG. 4f, after finishing the cleaning process of the substrate 101, a metal layer 124 including metal material (e.g., nickel) is deposited on the entire surface of the substrate 101, generally using a PVD or CVD process. Also, the metal layer 124 can comprise cobalt, titanium, tungsten, tantalum, molybdenum, or other metal or silicide-forming alloy having a high melting point.

Then, as shown in FIG. 4g, the semiconductor substrate 101 undergoes a salicide process including an annealing treatment (e.g., at a temperature and for a length of time sufficient to form a metal silicide), and the remaining metal layer 124 is removed. Thus, a salicide layer 113 is selectively formed on one or more portions of substrate, notably N+ type diffusion region 112 and possibly other source/drain terminals in the unit pixel (see, e.g., FIG. 2). In some examples, silicide in also partially formed on the gate electrode 105. Also, the metal silicide layer 113 can further comprise a nitride of cobalt, titanium, tungsten, tantalum, molybdenum, nickel or other metal having a high melting point.

The above-described method for manufacturing a CMOS image sensor according to the present invention has advantages as follows.

Firstly, forming upper and lower insulating layers, having different materials and thicknesses in the photo diode region, prevents salicidation of the photo diode region. Accordingly, an increase in dark current due to degradation of leakage characteristics of the photo diode can be prevented, reduced or suppressed. Ultimately, deterioration of dark image characteristics of the image sensor can be reduced or prevented.

Secondly, when the upper insulating layer is dry etched and the lower insulating layer is wet etched, plasma damage due to the dry etching process and undercuts due to the wet etching process can be minimized. Thus, dark current in the CMOS image sensor can be considerably decreased, and dark image characteristics can be improved. As a result, the yield of CMOS image sensors can be increased. Especially, variations in PMOS transistor threshold voltages can be minimized, thus resulting in improvement of device uniformity and/or reliability.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for manufacturing a CMOS image sensor, comprising the steps of:
forming a lower insulating layer and an upper insulating layer on an entire surface of a semiconductor substrate in successive order, the substrate having an isolation layer defining an active region comprising a photo diode region and a transistor region, the transistor region having a gate thereon, the gate comprising a gate insulating layer and a gate electrode, and having insulating sidewalls on sides thereof;
removing the upper and lower insulating layers from at least some regions of the substrate other than the photo diode region;
forming a metal layer on the entire surface of the semiconductor substrate; and
annealing the semiconductor substrate to selectively form a salicide layer on an exposed surface of the semiconductor substrate.

2. The method of claim 1, wherein the upper and lower insulating layers have a different thickness from each other.

3. The method of claim 2, wherein the upper insulating layer has a thickness of from 300 Å to 500 Å.

4. The method of claim 2, wherein the lower insulating layer has a thickness of from 150 Å to 200 Å.

5. The method of claim 1, wherein the lower insulating layer comprises silicon nitride.

6. The method of claim 1, wherein the upper insulating layer comprises a TEOS (Tetra Ethyl Ortho Silicate)-based oxide.

7. The method of claim 1, wherein the upper and lower insulating layers have a different etch selectivity from each other.

8. The method of claim 7, wherein removing the upper and lower insulating layers comprises the steps of:
dry etching the upper insulating layer; and
wet etching the lower insulating layer.

9. The method of claim 8, wherein dry etching the upper insulating layer comprises overetching at up to a 50% over etch ratio.

10. The method of claim 8, wherein wet etching the lower insulating layer uses an etchant including phosphoric acid (H₃PO₄).

11. The method of claim 1, wherein the upper and lower insulating layers are formed using a low pressure chemical vapor deposition (LPCVD) process.

12. The method of claim 1, further comprising:
forming the isolation layer on or in the semiconductor substrate;
forming the gate on the transistor region; and
forming insulating sidewalls on sides of the gate electrode.

13. A CMOS image sensor, comprising:
a semiconductor substrate including an isolation layer defining an active region comprising a photo diode region and a transistor region;
a gate including a gate insulating layer and a gate electrode formed on the semiconductor substrate;
insulating sidewalls on sides of the gate electrode;
lower and upper insulating layers on the photo diode region, the lower and upper insulating layers blocking a salicide layer from forming on the photo diode region; and
a salicide layer on the transistor region.

14. The CMOS image sensor of claim 13, wherein the lower and upper insulating layers have a different thickness from each other.

15. The CMOS image sensor of claim 14, wherein the upper insulating layer has a thickness of from 300 Å to 500 Å.

16. The CMOS image sensor of claim 14, wherein the lower insulating layer has a thickness of form 150 Å to 200 Å.

17. The CMOS image sensor of claim 13, the lower insulating layer comprises silicon nitride.

18. The CMOS image sensor of claim 13, wherein the upper insulating layer comprises an oxide.

19. The CMOS image sensor of claim 13, wherein the upper insulating layer comprises a TEOS-based oxide.

20. The CMOS image sensor of claim 13, wherein the upper and lower insulating layers have a different etch selectivity from each other.
